(19) United States
(12) Patent Application Publication
(10) Pub. No.: US 2016/0276559 A1
(43) Pub. Date: Sep. 22, 2016

(54) Light-Emitting Diode Package With Substantially In-Plane Light Emitting Surface and Fabrication Method

(71) Applicant: Toshiba Corporation, Tokyo (JP)

(72) Inventors: Chih-Wei Chuang, Albany, CA (US); Chao-Kun Lin, San Jose, CA (US); Kai Liu, Dublin, CA (US)

(21) Appl. No.: 14/661,379

(22) Filed: Mar. 18, 2015

(51) Int. Cl. H01L 33/62; H01L 33/00; H01L 33/50

(52) U.S. Cl. CPC H01L 33/62; H01L 33/502; H01L 33/005; H01L 2933/0033; H01L 2933/0041; H01L 2933/0066

(57) ABSTRACT

The present specification discloses a novel light emitting diode package having a package substrate with a light emitting layer bonded to the package substrate. Unlike conventional LED packages (such as those shown in FIGS. 1 and 2), the chip handling substrate typically located between the package substrate and the light emitting layer is not present. In addition, the LED package of the present specification may comprise an insulating layer formed on the package substrate and the light emitting layer. The LED package of the present specification may further comprise an interconnect metal formed on the insulating layer and the light emitting layer, wherein the interconnect metal electrically connects the light emitting layer to the package substrate.

### FIELD OF THE INVENTION

The present specification is a novel LED package and a fabrication method for making such a package.

### BACKGROUND OF THE INVENTION

FIG. 1 shows a conventional light-emitting diode (“LED”) package 100 comprising a package substrate 110 (e.g., aluminum nitride), metal layer 120, a silicone dome 130, an LED chip 140 comprising an LED chip handling substrate 140a (e.g., silicon) and a blue light emitting layer 140b, a thermal pad 150, and a bond wire 160 electrically connecting the LED chip 140 to the package substrate 110. Regarding the LED chip 140, the blue light emitting layer 140b typically has a thickness of under 5 μm while the LED chip handling substrate 140a typically has a thickness of 150 μm or greater. The LED chip handling substrate 140a is attached to the package substrate 110 through a die-attach process using die attach material (not shown), typically a few microns thick, between the LED chip 140 and the surface of the package substrate 110. The package substrate 110 may be comprised of high thermal conductivity materials such as aluminum nitride. The package substrate 110 also may comprise a recess 120a in the metal layer 120 for electrical isolation purposes to isolate package solder pads 120b and 120c. In one embodiment, package solder pad 120b is an anode and package solder pad 120c is a cathode (the polarity of the package solder pads 120b and 120c can be swapped depending on the detailed structure of the LED chip 140).

A conventional LED package 100 typically requires the fabrication of the LED chip 140 by attaching an LED epitaxial wafer comprising the blue light emitting layer 140b to a LED chip handling substrate 140a, e.g., silicon. The next step comprises attaching the LED chip 140 onto the package substrate 110 using, for example, a die-attach material. Then, after the LED chip 140 is attached to the package substrate 110, a bond wire 160 is necessary to connect the LED bond pads (either p-pad or n-pad) 170a to an package bond pad 170b. The bond wire 160 and bond pads 170a and 170b are used to connect the LED chip to the package. As an example, in FIG. 1 the LED chip handling substrate 140a is n-type and the LED chip bond pad 170a is p-type. Therefore, package solder pad 120b is a cathode and pad 120c is an anode. The next step forms a transparent silicone dome 130 over the LED package 100.

For a conventional LED package 100, the distance, h, between the surface of the blue light emitting layer 140b to the surface of the metal layer 120 is a sum of their thicknesses. In the example of FIG. 1, the distance, h, has a conventional thickness of between 150-155 μm. As a result, conventional LED packages, such as the one shown in FIG. 1, usually have their light emitting surface at least 150 μm higher than the package surface due to the presence of the chip handling substrate underneath the light emitting layers. This distance, h, dictates the amount of silicone necessary to form the silicone dome 130 that encapsulates the LED package 100. To maximize the light extraction efficiency of the LED package 100, the silicone dome 130 must be a certain distance from the surface of the blue light emitting layer 140b. Therefore, because of the thickness of the LED chip handling substrate 140a, the silicone dome 130 has a base portion 130a to provide the appropriate distance between the silicone dome 130 and the blue light emitting layer 140b.

FIG. 2 shows a cross-section view of a conventional white LED package 200, comprising package substrate 210 (e.g., aluminum nitride), metal layers 220, a silicone dome 230, an LED chip 240 comprising an LED chip handling substrate 240a (e.g., silicon), a blue light emitting layer 240b, and phosphor layer 240c, a thermal pad 250, and a bond wire 260 electrically connecting the LED chip 240 to the package substrate 210 using bond pads 270a and 270b. The primary difference between a white LED package and a blue LED package is the additional phosphor layer 240c having a thickness of approximately 50 μm and positioned on top of the blue emitting layer 240b. Because of the additional phosphor layer 240c being positioned on the light emitting layer 240b, the size of the silicone dome 230 may be increased in comparison to the blue LED package 100 of FIG. 1. The base portion 230a of the silicone dome 230 in FIG. 2 is correspondingly increased in comparison to the blue LED package shown in FIG. 1.

As can be seen from the foregoing description, conventional LED packages and the fabrication processes for making them suffer from several disadvantages including, but not limited to, costs associated with the extra silicone required to form the base portion 130a of the silicone dome 130, and the extra steps and material associated with forming an LED die 140 including the LED chip handling substrate 140a and the bond wire 160.

There is therefore a long felt need for an LED package that overcomes these disadvantages and can be manufactured and packaged at reduced costs while maintaining the light emission performance of current LED devices.

### BRIEF DESCRIPTION OF THE INVENTION

Generally, the present specification discloses a novel LED package and a novel fabrication method for making such a package.

In one embodiment, the novel light emitting diode package may comprise a package substrate with a light emitting layer bonded to the package substrate. Unlike conventional LED packages (such as those shown in FIGS. 1 and 2), a chip handling substrate that is traditionally located between the package substrate and the light emitting layer is not present. In addition, the LED package of the present specification may comprise an insulating layer formed on the package substrate and the light emitting layer. The LED package of the present specification may further comprise an interconnect metal formed on the insulating layer and the light emitting layer, wherein the interconnect metal electrically connects the light emitting layer to the package substrate. Unlike conventional LED packages, there is no bond wire that electrically connects the light emitting layer to the package substrate. The novel structure of the LED package, for example, reduces the amount of materials necessary to fabricate the package.

In one embodiment, a novel fabrication method for making such a package is disclosed. This fabrication method may include the step of bonding a light emitting layer of an LED epitaxial wafer directly to a package substrate. The LED epitaxial wafer may also comprise a silicon substrate attached to the light emitting layer. The light emitting layer may then be exposed after having bonded the light emitting layer to the package substrate by removing the silicon substrate of the LED epitaxial wafer. Once the silicon substrate has been removed, the fabrication method may then utilize wafer level processing to form an insulating layer on both the package substrate and the exposed light emitting layer and then forming a metal interconnect layer on the insulating layer and the exposed light emitting layer.

The fabrication process, for example, takes advantage of wafer-level processing to reduce costs of fabricating the package.

### BRIEF DESCRIPTION OF THE FIGURES

FIG. 1 illustrates a conventional blue LED package.

FIG. 2 illustrates a conventional white LED package.

FIG. 3A illustrates an LED package according to one embodiment of the present specification.

FIG. 3B provides a magnified view of various components of the LED package shown in FIG. 3A.

FIG. 4 illustrates an LED package according to one embodiment of the present specification.

FIGS. 5A-5J each illustrates steps of a fabrication method according to one embodiment of the present specification.

FIGS. 6A-6C each illustrates steps of fabrication method according to one embodiment of the present specification.

FIGS. 7A-7E each illustrates steps of a fabrication method according to one embodiment of the present specification.

### DETAILED DESCRIPTION OF THE INVENTION

A novel LED package structure and a fabrication method for making such a structure will now be described more fully with reference to the accompanying drawings. The drawings are not necessarily drawn to scale and certain features of the invention may be shown exaggerated in scale or in schematic form in the interest of clarity and conciseness.

In describing various embodiments, specific terminology is employed for the sake of clarity. However, the invention is not intended to be limited to the specific terminology used in this specification. It is to be understood that each specific element includes all technical equivalents which operate in a similar manner to accomplish a similar purpose.

Certain embodiments of the invention provide a novel LED package, and a fabrication method for making such a package, where an LED epitaxial wafer is directly bonded to an LED package substrate. Advantageously, the conventional intermediate step of forming a LED chip comprising the LED epitaxial wafer and a chip handling substrate is eliminated. The result is a novel LED package where the light emitting surface of an LED chip is substantially planar with the surface of the package substrate.

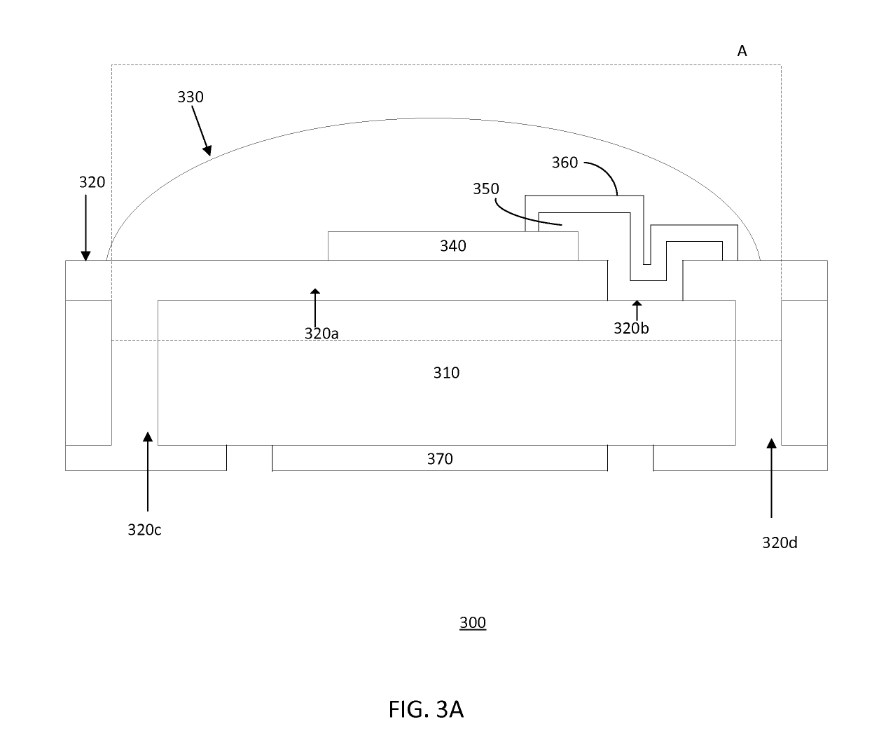

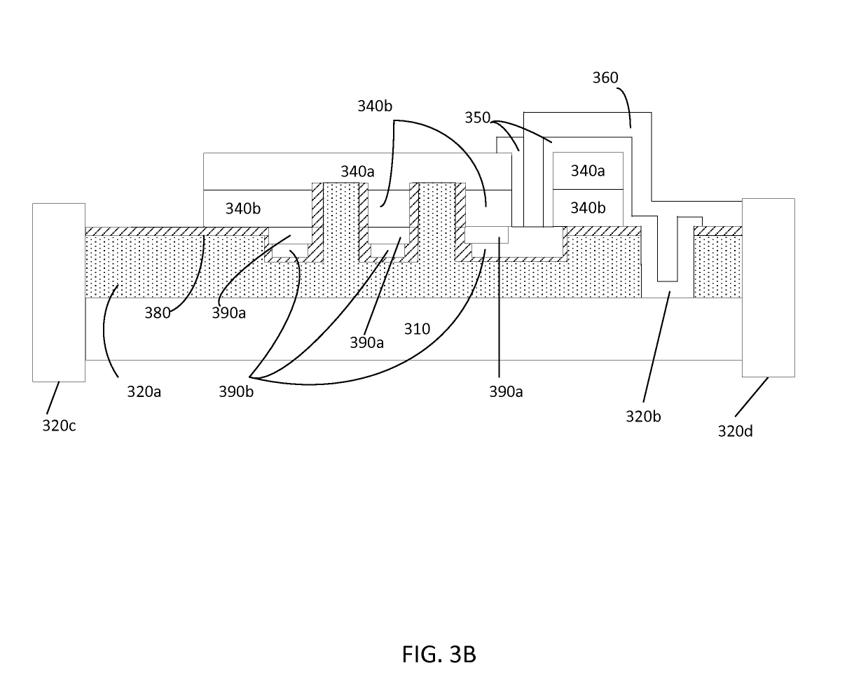

FIG. 3A discloses a LED package 300 according to one embodiment of the present specification. LED package 300 comprises a substrate 310, such as aluminum nitride (AlN), metal layers 320, silicone dome 330, light emitting layer 340, an insulation layer 350, metal interconnect layer 360, and a thermal pad 370. The metal layer 320 is formed on substrate 310 and includes a bonding metal layer 320a and a recess 320b. The bonding metal layer 320a functions to bond the light emitting layer 340 to the substrate 310 and provide electrical connection to package solder pad 320c, which can function as a cathode. Package solder pad 320d can function as an anode.

The insulation layer 350 is formed on the light emitting layer 340 and within the recess 320b of the metal layers 320. The recess 320b allows the insulation layer 350 to be in contact with the substrate 310 through the metal layer 320. As a result, package solder pads 320c and 320d are electrically isolated from each other. The metal interconnect layer 360 is formed on the insulation layer 350.

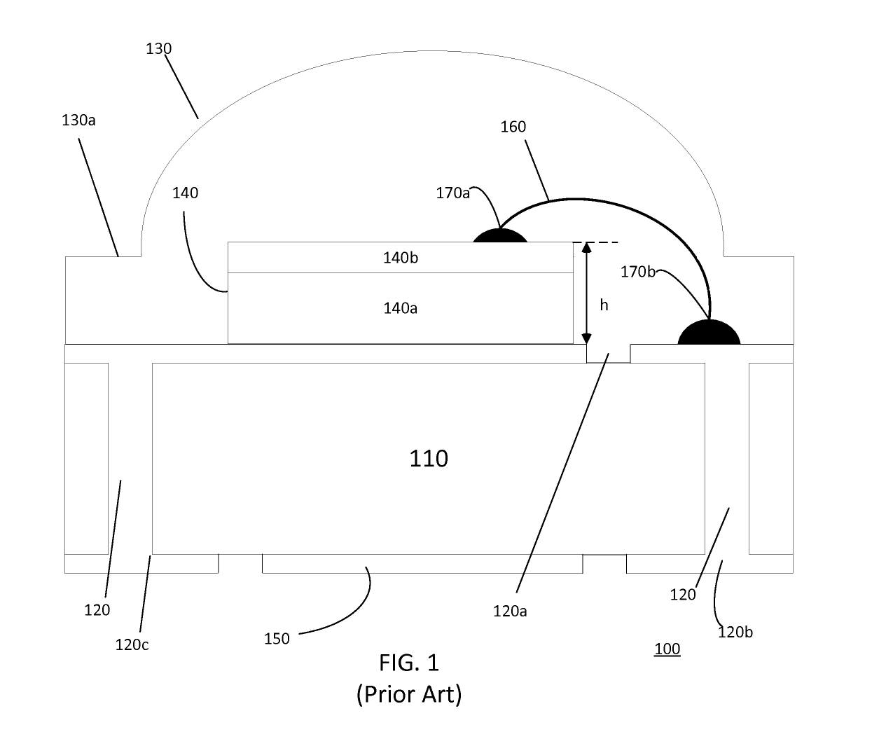

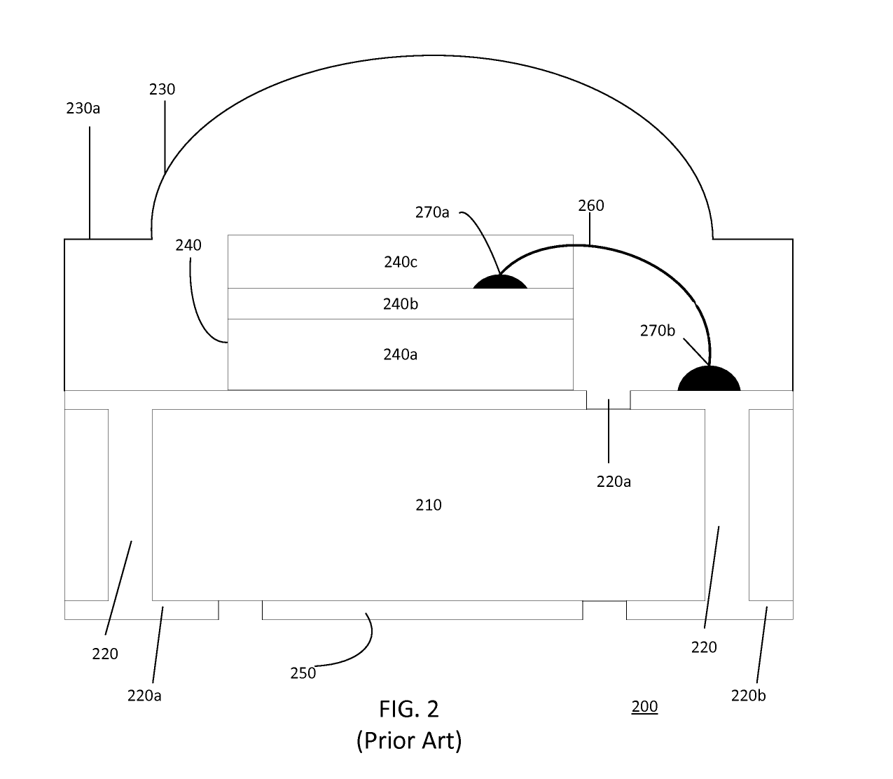

In contrast to conventional LED packages, the light emitting layer 340 is formed on metal layer 320 without an intermediary chip handling substrate such as elements 140a and 240a as discussed with regard to FIGS. 1 and 2, respectively. The shorter the distance between the surface of light emitting layer 340 to the surface of the package metal surface 320, the lower the amount of silicone necessary to encapsulate the LED package 300. Using less silicone for the silicone dome 330 reduces the costs of fabricating an LED package. As a result of the absence of the conventional chip handling substrate, the distance from the surface of the light emitting layer 340 to the surface of the substrate 310 is substantially reduced. Consequently, the silicone dome 330 of the present specification does not require a base portion. The elimination of the base portion of the silicone dome found in a conventional LED package further reduces the amount of silicone necessary to form the silicone dome 330.

Further in contrast to conventional LED packages, insulation layer 350 and metal interconnect layer 360 replaces a conventional fragile bond wire (e.g., 160 in FIGS. 1 and 260 in FIG. 2) which connects an LED chip to the package substrate in conventional LED packages. That is, metal interconnect layer 360 is not a wire. In the present embodiment, the light emitting layer 340 is electrically connected to the package solder pad 320d of the package 300 through the metal interconnect layer 360. Light emitting layer 340 is in direct contact with bonding metal layer 320a which provides electrical connection to package solder pad 320c.

FIG. 3B provides a magnified view of region A of the LED package 300 in FIG. 3A.

Region A includes the light emitting layer 340, the insulation layer 350, metal interconnect layer 360, bonding metal layer 320a, and substrate 310. The light emitting layer 340 may comprise an n-type gallium nitride (“n-GaN”) layer 340a and a p-type gallium nitride (“p-GaN”) layer 340b. The formation of package solder pads 320c and 320d may be interchangeable depending which piece is electrically connected to the n-GaN layer 340a and the p-GaN layer 340b. Package solder pad 320c is electrically connected to the n-GaN layer 340a and is therefore a cathode. Package solder pad 320d is electrically connected to the p-GaN layer 340b and is therefore an anode.

Also depicted in FIG. 3B are a protection metal layer 390b, a reflection layer 390a and a bonding metal layer 320a that is part of the metal layer 320 (shown in FIG. 3A). Bonding metal layer 320a may comprise different layers (not shown). In one embodiment, the portion of the bonding metal layer 320a that is in contact with n-GaN 340a provides current injection from bonding metal layer 320a to n-GaN layer 340a.

Regarding the reflection layer 390a, it can be surrounded by the protection metal layer 390b. Reflection layer 390a may be formed of a reflective material such as silver and/or nickel. The reflection layer 390a is provided for reflecting light that is emitted by the light emitting layer 340 toward the surface of the substrate 310. Regarding the protection metal layer 390b, it protects the surface of reflection film 390a from being in contact with chemicals used in subsequent fabrication processes.

Dielectric layer 380 is also deposited on the LED package. The dielectric layer 380 passivates and insulates reflection film 390a and protection metal layer 390b from the bonding metal layer 320a. Isolation of the reflection 390a and protection metal layer 390b from the bonding metal layer 320a is necessary because the reflection film 390a and protection metal layer 390b are in contact with p-GaN layer 340b while the bonding metal layer 320a is in contact with n-GaN layer 340a.

The light emitting layer 340, the reflection layer 390a, and the protection metal layer 390b are bonded to substrate 310 via the bonding metal layer 320a. The light emitting layer 340 is further connected to the package solder pad 320c of the package 300 via the bonding metal layer 320a. Insulation layer 350 is formed on the light emitting layer 340 and the bonding metal layer 320a. The insulation layer 350 also is formed within recess 320b of the bonding metal layer 320a. Metal interconnect layer 360 is then formed on the insulation layer 350 and is connected to the package solder pad 320d of the package 300.

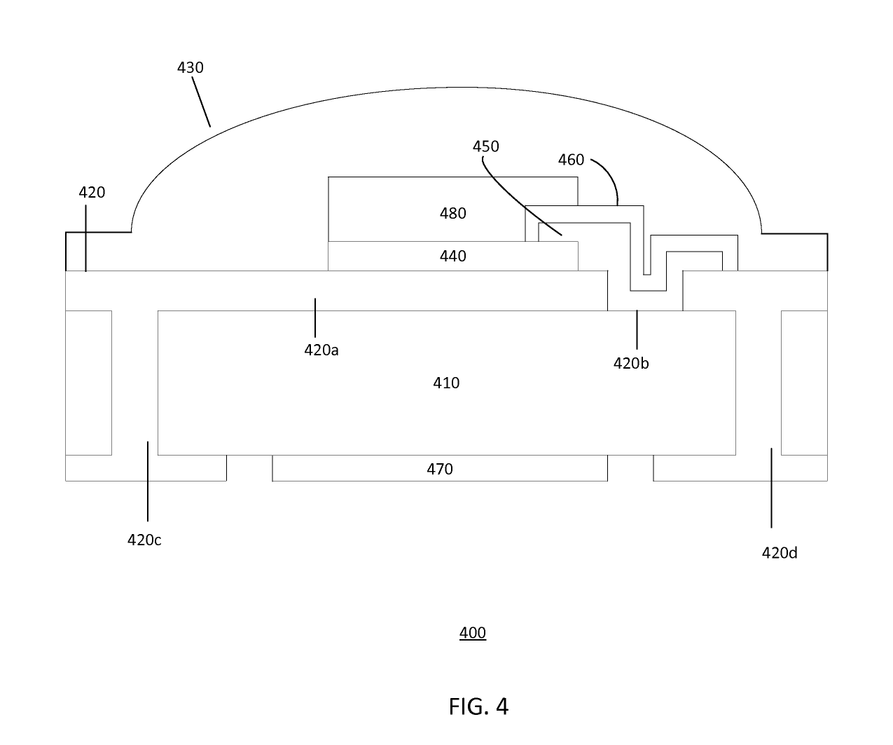

FIG. 4 discloses a LED package 400 according to an embodiment of the present specification. LED package 400 comprises a substrate 410 (e.g., aluminum nitride), metal layer 420, a silicone dome 430, a light emitting layer 440, an insulation layer 450, a metal interconnect layer 460, a thermal pad 470, and a phosphor layer 480 which changes the wavelength of light emitted by the light emitting layer 440. More specifically, the phosphor layer 480 is located on the light emitting layer 440, the insulation layer 450, and the metal interconnect layer 460. In one embodiment, the phosphor layer 480 can have a thickness of approximately 50 μm. Insulation layer 450 and metal interconnect layer 460 is in contact with the substrate 410 through recess 420b in the metal layer 420. The light emitting layer 440 is connected to package solder pad 420c of the package 400. Package solder pad 420c may be, for example, a cathode. Metal interconnect layer 460 is then formed and are connected to the package solder pad 420d, which may be, for example, an anode.

There are several benefits that result from the novel LED structures disclosed above. For example, there is a reduction in costs for both materials and the manufacturing process. With regard to materials, the silicone domes (e.g., 330 in FIG. 3A and 430 in FIG. 4) can be made smaller and brought closer to the surface of the package (e.g., 300 in FIG. 3A and 400 in FIG. 4) which reduces the amount of material (and therefore the cost) of the silicone dome. The lack of a conventional chip handling substrate (e.g., 140a in FIGS. 1 and 240a in FIG. 2) also reduces the amount of materials (and therefore the cost) needed to fabricate the LED package.

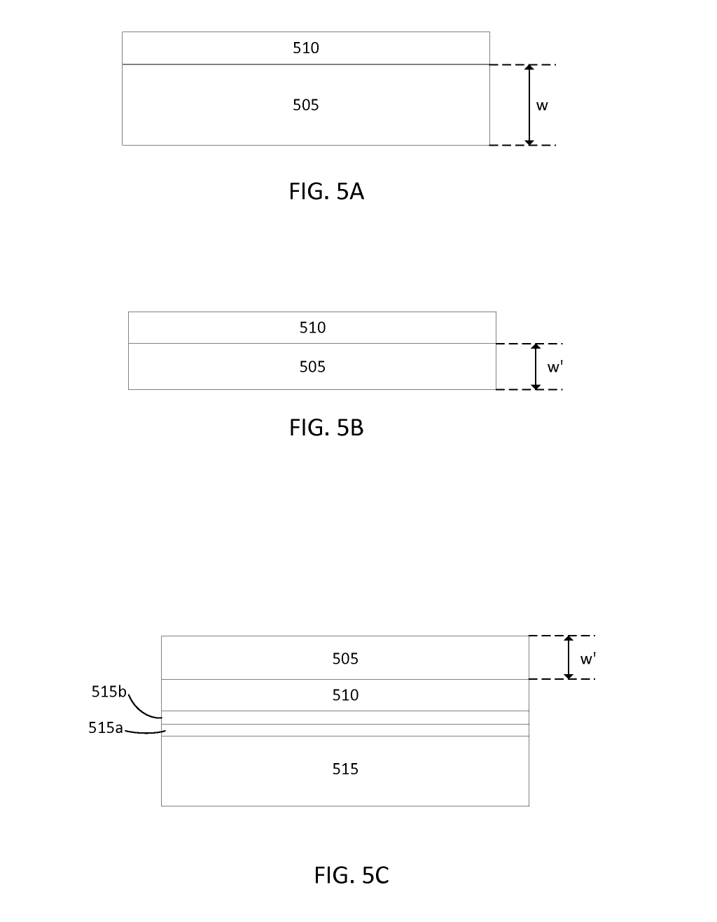

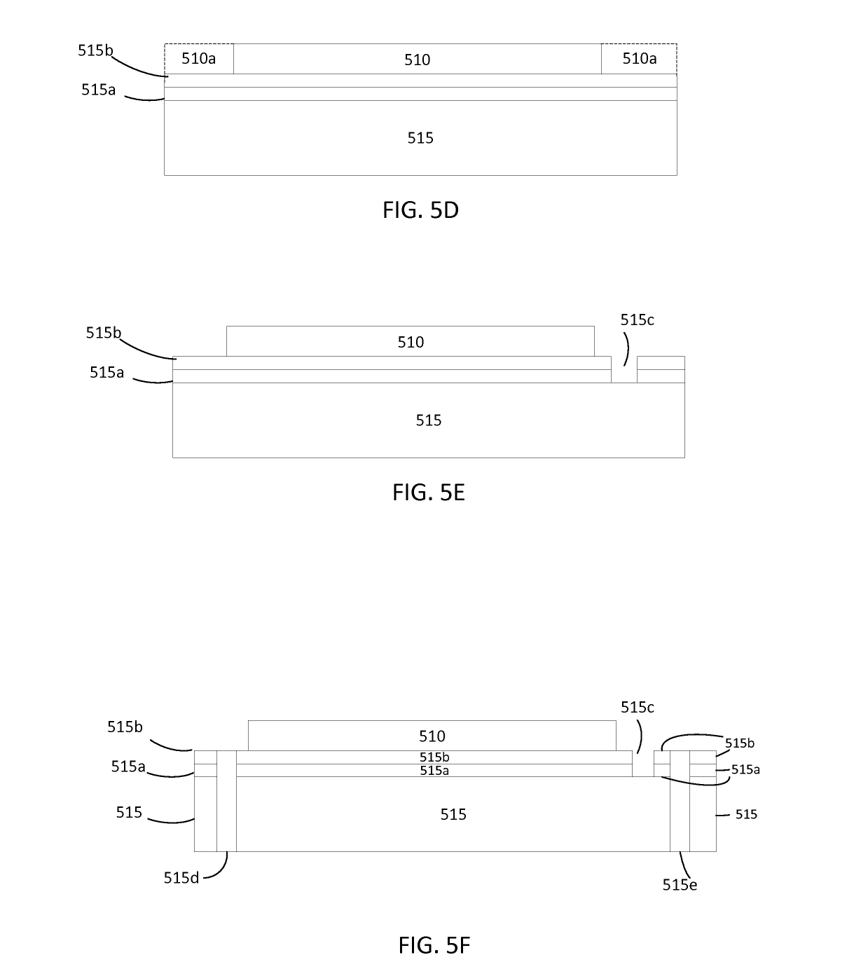

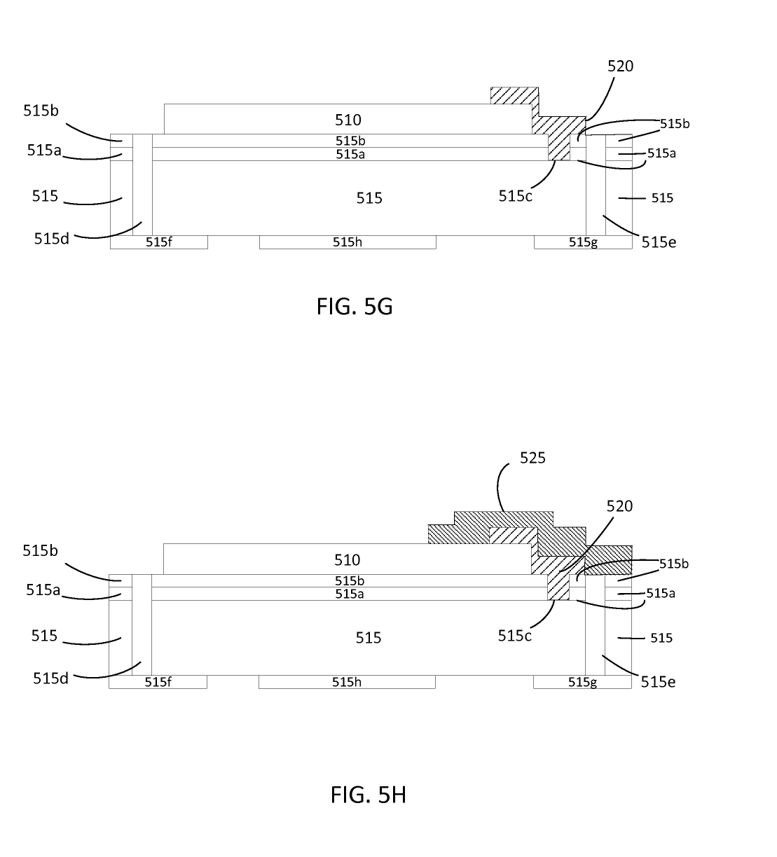

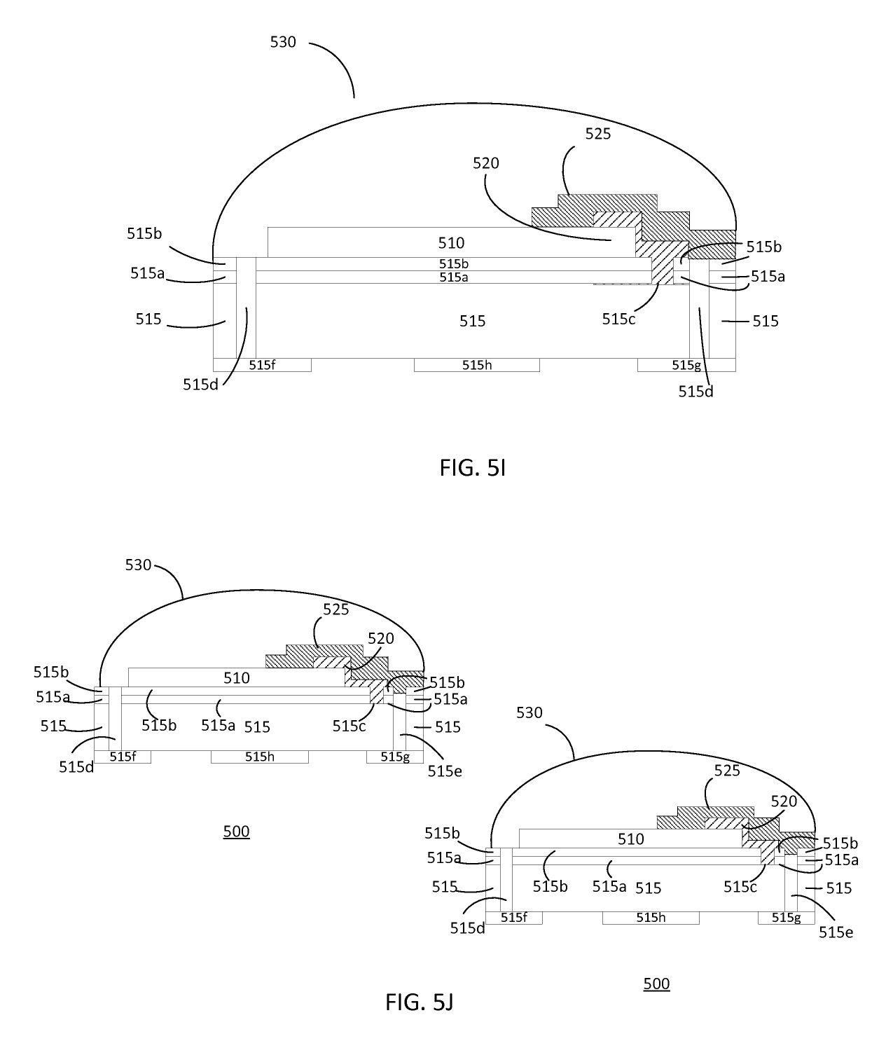

With regard to the manufacturing process, conventional steps that required die-level processing can be replaced with wafer-level processing steps. For example, with regard to FIG. 3A, because the light emitting layer 340 is directly bonded to the substrate 310, intermediate steps such as attaching substrates to the light emitting layer 340 have been eliminated. The step of die attaching LED chips onto package substrates is also eliminated. And finally, wire bonding is replaced by the wafer-level interconnect metal patterning. By replacing conventional die-level processing with wafer-level processing level new package method will reduce the overall fabrication cost. The steps of the fabrication process will be discussed in more detail below with regard to FIG. 5.

The LED package of the present specification also provides an improvement in the performance of the LED package in comparison to conventional LED packages. The elimination of a conventional chip handling substrate (e.g., e.g., 140a in FIGS. 1 and 240a in FIG. 2) improves the efficiency of thermal dissipation because the light emitting layer (e.g., 340 in FIG. 3A and 440 in FIG. 4) sits directly on the package, which is the main heat dissipation path for the emitting layer. This configuration is in contrast to conventional LED packages where the light emitting layer (e.g., 140b in FIGS. 1 and 240b in FIG. 2) sits on top of a chip handling substrate (e.g., 140a in FIGS. 1 and 240a in FIG. 2) and die-attach material (which attaches the chip handling substrate to the LED substrate).

The novel LED packages described above are achieved by a novel fabrication method in which the semiconductor light emitting layers are directly transferred, via wafer bonding, onto the package surface without the conventional step of forming an LED chip having a chip handling substrate. FIGS. 5A-5J show the steps of the fabrication method of an LED package according an embodiment of the present specification. In contrast to fabrication methods of conventional LED packages, the steps of the present specification can all be performed using wafer level processing. While only one LED package is shown in the figures, one of ordinary skill in the art would understand that the process would apply to a plurality of LED packages on a wafer.

First, in FIG. 5A, a light emitting layer 510 is grown on an epitaxial growth substrate 505. The light emitting layer 510 may comprise gallium nitride (GaN) and the epitaxial grown substrate 505 may comprise silicon. The growth substrate 505 has a certain thickness, w.

In FIG. 5B, the growth substrate 505 is thinned, for example, using a mechanical grinding process and the new thickness, w′, of the substrate is less than thickness, w. As an example, in one embodiment, the light emitting layer 510 is grown on a 1 mm thick growth substrate 505 and the thinning step may reduce the thickness of the growth substrate 505 from 1 mm to approximately 350 μm.

In FIG. 5C, one side of the light emitting layer 510 is first coated with a bonding metal to form a bonding metal layer 515b. The bonding metal layer 515b is then bonded to the bonding metal layer 515a of package substrate 515. The presence of the thinned growth substrate 505 (with thickness, w′) prevents the growth substrate 505 and light emitting layer 510 from breaking when bonded to the package substrate 515, which can occur as a result of the differences in thermal expansion coefficients between the growth substrate 505 and the package substrate 515. The result of the step shown in FIG. 5C is a package with light emitting layer directly bonded to the surface of the package substrate 515.

The step shown in FIG. 5C is in contrast to conventional fabrication methods because there are no intermediate steps such as attaching a chip handling substrate (for example, the LED chip handling substrate 140a, shown in FIG. 1) to a light emitting layer (for example, the blue light emitting layer 140b, shown in FIG. 1) to create an LED chip (for example, the LED chip 140, shown in FIG. 1), and then die-attaching the created LED chip onto a package substrate (for example, the conventional LED package 100 in FIG. 1). In one embodiment, the fabrication method disclosed herein eliminates these intermediate steps.

In FIG. 5D, the growth substrate 505 is removed from the light emitting layer 510. The light emitting layer 510 is also partially etched to remove portions 510a of the light emitting layer 510 to define the individual light emitting layer 510 on the packaging substrate 515. This removing step can be performed using, for example, chemical etching.

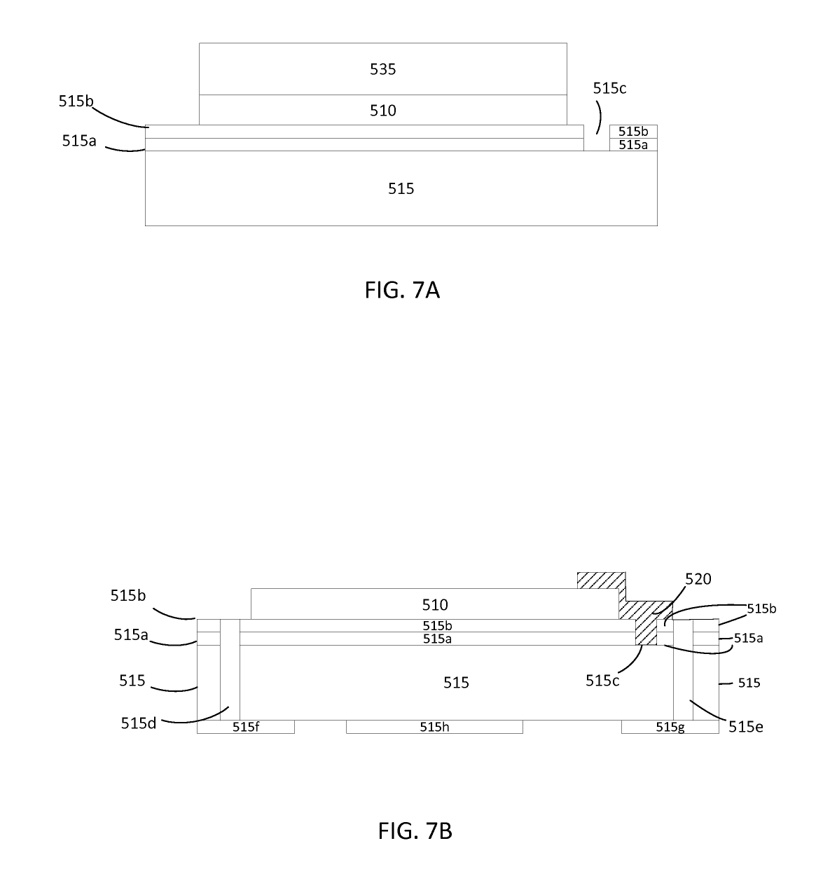

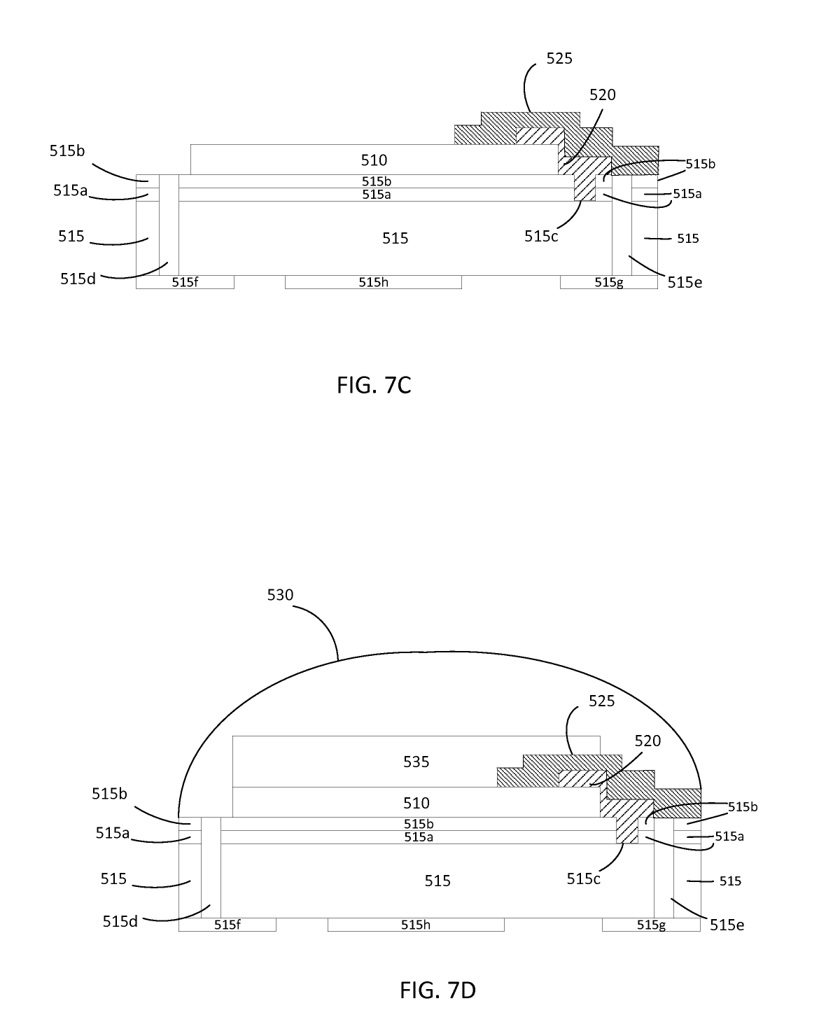

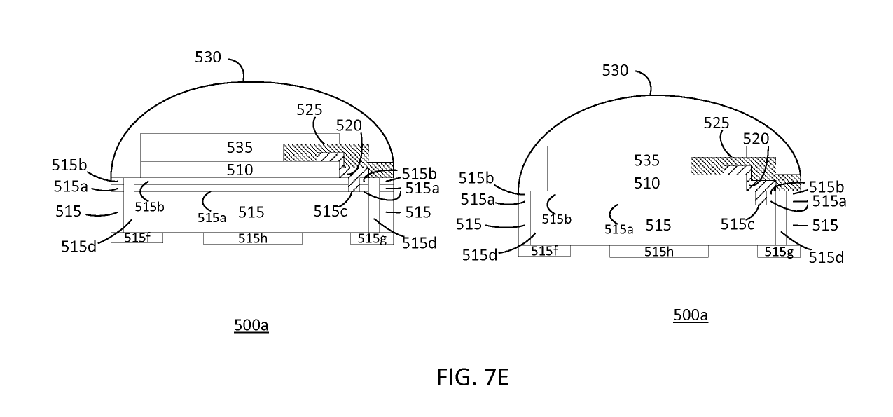

FIGS. 5E-5J shows the steps performed for fabricating an LED package without applying a phosphor layer on the light emitting layer 510 (which is discussed below with reference to FIGS. 7A-7E.

In FIG. 5E, portions of the bonding metal layers 515a and 515b are etched away to form a recess 515c.

In FIG. 5F, holes are drilled through bonding metal layers 515a and 515b, and package substrate 515, which are then filled with metal to form package solder pads 515e and 515d. Package solder pad 515e may be an anode and package solder pad 515d may be a cathode.

In FIG. 5G, with the growth substrate 505 removed, portions 510a of the light emitting layer 510 etched away, and recess 515c formed, as described in the previous steps, an insulating layer 520 is then formed on the light emitting layer 510, on the bonding metal layers 515b, and in the recess 515c. Additionally, electrical pads 515g and 515f, as well as the thermal pad 515h are deposited. Electrical pad 515g is in connection with package solder pad 515e, electrical pad 515f is in connection with package solder pad 515d, and thermal pad 515h is in connection with package substrate 515.

FIG. 5H illustrates the formation of a metal interconnect layer 525 on the insulating layer 520 and on the light emitting layer 510. The steps shown in FIGS. 5G and 5H effectively replace the step of attaching a bond wire in conventional fabrication methods of LED packages. The fabrication cost is reduced because gold wire bonding, which is serial process with one wire bonding after another, is no longer needed.

FIG. 5I illustrates the formation of a silicone dome 530. FIG. 5J illustrates the step of package singulation by dicing the package, which results in forming the individual packages 500 from the wafer (not shown).

As a consequence of these process steps, the light emitting surface 510 is nearly in the same plane as the surface of the package metal surface 515b. The silicone dome 530 of the present specification does not require a base portion to maintain the light extraction efficiency of the LED device from an optical property point of view, since the chip handling substrate is no longer present. In comparison to a conventional package dome size (e.g., as depicted in FIGS. 1 and 2), the silicone dome 530 of the present specification uses less silicone while maintaining the light extraction efficiency of the LED.

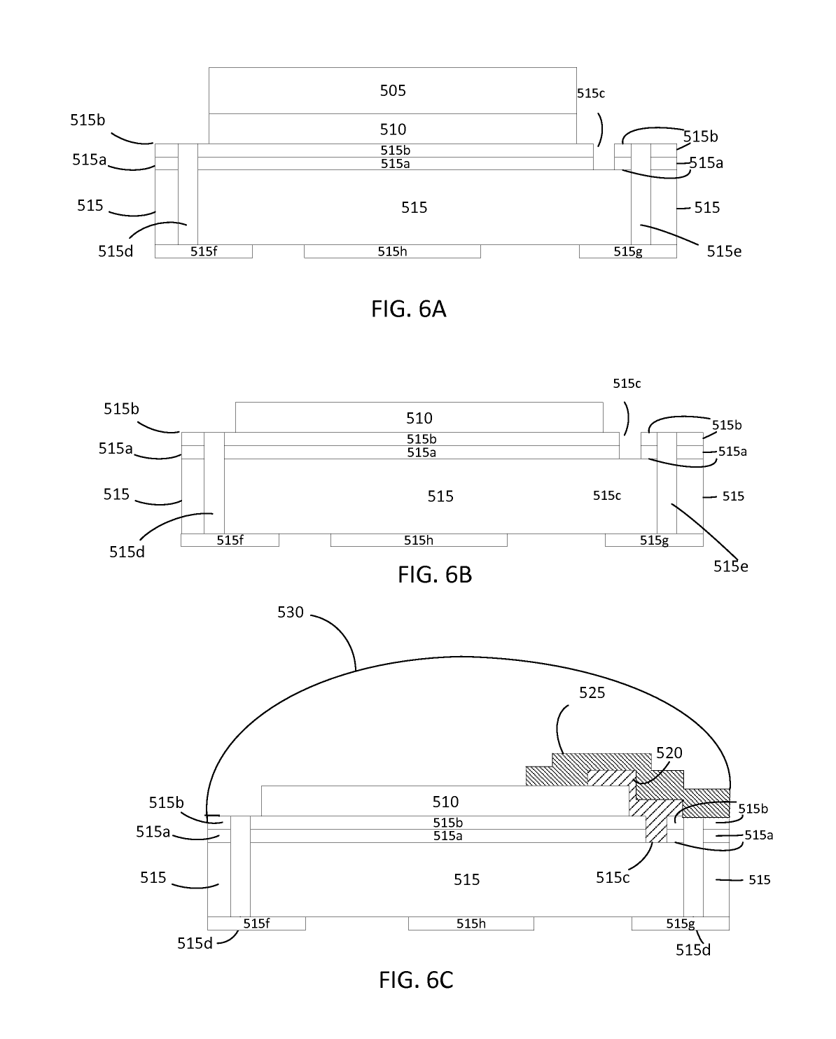

FIGS. 6A-6C illustrate another embodiment for forming the LED package 500. In this embodiment, package solder pad 515d (which, for example, may be a cathode), package solder pad 515e (which, for example, may be an anode), and recess 515c are preformed in the package substrate 515 prior to bonding the light emitting layer 510 and growth substrate 505. This is in contrast to the embodiment provided in FIGS. 5E and 5F which form the recess 515c and package solder pads 515d and 515e after bonding the light emitting layer 510 to the package substrate 515.

FIG. 6B illustrates the step removing the growth substrate 505 from the light emitting layer 510 after the light emitting layer 510 is bonded to the package substrate 515 with the preformed package solder pads 515d and 515e, and recess 515c.

FIG. 6C shows the subsequent steps that are performed on the package substrate 515 which are similar to the steps shown in FIGS. 5G-5J, with the formation of the insulating layer 520, the metal interconnect layer 525, and the silicone dome 530.

The fabrication methods described in FIGS. 5A-5J may also be applied to LED packages having a phosphor coating 535 applied over the light emitting layer 510 as will now be described with respect to FIGS. 7A-7E.

FIGS. 7A-E show steps that occur after the growth substrate 505 is removed from the light emitting layer 510 and portions 510a of the light emitting layer 510 are etched away as described above with respect to FIG. 5D. Subsequent to removing the growth substrate 505 and etching the light emitting layer 510, FIG. 7A illustrates the step of etching the bonding metal layers 515a and 515b to form recess 515c. In contrast to conventional LED package fabrication, the application of the phosphor layer 535 can be performed using a wafer-level process, which is not possible in conventional LED packages due to the presence of a fragile bond wire. Performing, using wafer-level processing, steps that are traditionally performed at the die-level (i.e., each individual die), such as the formation of a bond wire or application of the phosphor layer, allows processes to be performed across the entire wafer. Steps performed using wafer-level processing therefore generally saves costs when compared to comparable steps performed using die-level processing.

The remaining steps are similar to those described with respect to FIGS. 5G-J. In FIG. 7B, an insulating layer 520 is formed on the light emitting layer 510, the bonding metal layer 515b, and in the recess 515c. FIG. 7C illustrates the formation of a metal interconnect layer 525 formed on the insulating layer 520 and light emitting layer 510 and the subsequent deposition of phosphor layer 535 on top of the light emitting layer 510. As previously discussed, these steps effectively replace the conventional step of attaching a bond wire. The fabrication cost is reduced in comparison to a conventional fabrication method because gold wire bonding, is a die-level process which requires serially attaching one wire bonding to each package, is no longer necessary. FIG. 7D illustrates the formation of a silicone dome 530. Next, FIG. 7E illustrates the formation of multiple LED packages through package singulation by dicing the wafer.

As previously discussed, the addition of a phosphor layer 535 on top of the light emitting layer 510 changes the wavelength of light emitted by the light emitting layer 510. Due to the elimination of the LED chip handling substrate, the phosphor layer 535 is closer to the surface of the package as compared to conventional LED packages. With the elimination of the LED chip handling substrate, the silicone base of the silicone dome can be reduced in comparison to conventional bases for LED packages having phosphor. Therefore, the dome size for LED packages having a phosphor layer can also be smaller than conventional LED packages, while maintaining the light extraction efficiency.

Other objects, advantages and embodiments of the various aspects of the present specification will be apparent to those who are skilled in the field of the invention and are within the scope of the description and the accompanying Figures. For example, but without limitation, structural or functional elements might be rearranged consistent with the present specification. Similarly, principles according to the present specification could be applied to other examples, which, even if not specifically described here in detail, would nevertheless be within the scope of the present specification.

What is claimed is:

1. A light emitting diode package, comprising:
a substrate;
a bonding layer disposed on a surface of the substrate and having a first portion of the bonding layer electrically isolated from a second portion of the bonding layer;
a first solder pad electrically connected to the first portion of the bonding layer;
a second solder pad electrically connected to the second portion of the bonding layer;
a light emitting layer having a first semiconductor layer of a first conductivity type and a second semiconductor layer of a second conductivity type that is different from the first conductivity type, the light emitting layer disposed on the first portion of the bonding layer;
an insulating layer formed in a recess between the first portion of the bonding layer and the second portion of the bonding layer; and
an interconnect layer formed on the insulating layer and the light emitting layer,
wherein
the interconnect layer electrically connects the second semiconductor layer and the second solder pad, and
the first portion of the bonding layer electrically connects the first semiconductor layer and the first solder pad.

2. The light emitting diode package of claim 1, wherein the bonding layer comprises a metal layer and the light emitting layer is directly bonded to the metal layer on an upper surface of the substrate.

3. (canceled)

4. The light emitting diode package of claim 2, wherein the metal layer comprises the recess exposing a portion of the substrate, and a portion of the insulating layer is in contact with the exposed portion of the substrate.

5. (canceled)

6. (canceled)

7. The light emitting diode package of claim 1, wherein a thickness of the light emitting layer is equal to a distance from an upper surface of the bonding layer to an upper surface of the light emitting layer.

8. The light emitting diode package of claim 1, wherein the light emitting layer has a thickness of 5 micrometers and wherein a distance from a top surface of the metal layer and a top surface of the light emitting layer is 5 micrometers.

9. The light emitting diode package of claim 1, further comprising:
a phosphor layer formed on the light emitting layer.

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. The light emitting diode package of claim 1, wherein each of the first solder pad and the second solder pad extend from a first surface of the substrate to a second surface of the substrate opposite of the first surface.

22. The light emitting diode package of claim 1, wherein the interconnect layer is disposed on a surface of the second portion of the bonding layer and an upper surface of the first solder pad.

23. The light emitting diode package of claim 1, wherein the interconnect layer is disposed on a surface of the second portion of the bonding layer.

24. The light emitting diode package of claim 21, wherein the interconnect layer is disposed on a surface of the second portion of the bonding layer and a surface of the second solder pad.

25. The light emitting diode package of claim 21, wherein the interconnect layer is disposed on a surface of the second portion of the bonding layer.

26. The light emitting diode package of claim 1, further comprising a dome formed over the light emitting layer and having curved upper surface extending from an upper portion of the first solder pad to an upper portion of the second solder pad.

27. The light emitting diode package of claim 1, wherein the light emitting layer is disposed on the first portion of the bonding layer but not the second portion of the bonding layer.

28. The light emitting diode package of claim 1, wherein the interconnect layer electrically connects the second semiconductor layer, the second bonding layer, and the second solder pad.
